(19) United States
(12) Patent Application Publication
(10) Pub. No.: US 2008/0315219 A1
(43) Pub. Date: Dec. 25, 2008

(54) LIGHT EMITTING DIODE LIGHT SOURCE DEVICE

(75) Inventor: Ching Ho, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AMA PRECISION INC., Taipei (TW)

(21) Appl. No.: 12/142,807

(22) Filed: Jun. 20, 2008

(30) Foreign Application Priority Data
Jun. 22, 2007 (TW) 96122442

(51) Int. Cl. H01L 33/00

(52) U.S. Cl. 257/89; 257/E33.001

(57) ABSTRACT

A light emitting diode (LED) light source device includes a plurality of LED modules, a base and a clip. The base has a first base body, a second base body, and a third base body. The second base body and the third base body extend from two sides of the first base body and are corresponding to each other. The LED modules are provided at inside surfaces of the first base body, the second base body and the third base body. The clip holds the LED modules and fastens the second base body and the third base body to enable the LED modules to be tightly assembled at the base.

### CROSS-REFERENCE TO RELATED APPLICATION

This application claims the priority benefit of Taiwan application serial no. 96122442, filed on Jun. 22, 2007. The entirety of the above-mentioned patent application is hereby incorporated by reference herein and made a part of this specification.

### BACKGROUND OF THE INVENTION

1. Field of the Invention

The invention relates to a light source device and, more particularly, to a light emitting diode (LED) light source device.

2. Description of the Related Art

In recent years, since a light emitting diode (LED) has a small volume and a long service life, the LED has been broadly applied to various electronic products. For example, a digital light processing projector (DLP projector), a liquid crystal display projector (LCD projector) or other optical projection device with high brightness usually uses an LED source device with high brightness as its light source.

Generally speaking, the LED light source device 100 includes a red light LED module 110, a green light LED module 120 and a blue light LED module 130 (please refer to FIG. 1 which is a schematic diagram showing a conventional LED light source device). The red light LED module 110, the green light LED module 120 and the blue light LED module 130 are assembled on a base 150 via fasteners 140 such as screws.

However, since the base 150 is U-shaped and the red light LED module 110, the green light LED module 120 and the blue light LED module 130 are disposed at the upper wall 152 and two side walls 154 of the base 150, when an operator assembles the green light LED module 120 and the blue light LED module 130 to the side walls 154 of the base 150, the assembly tool such as a screwdriver may interfere with the base 150 during a locking process, and then the green light LED module 120 and the blue light LED module 130 cannot be screwed by the screws. Therefore the assembly efficiency is bad.

### BRIEF SUMMARY OF THE INVENTION

The invention provides an LED light source device which is easy to be assembled.

The invention provides an LED light source device which includes a plurality of LED modules, a base and a clip. The base has a first base body, a second base body and a third base body. The second base body and the third base body are formed by bending two sides of the first base body and are corresponding, and the LED modules are provided at inside surfaces of the first base body, the second base body and the third base body. The clip holds the LED modules. The clip fastens the second base body and the third base body to enable the LED modules to be tightly assembled at the base.

In one embodiment of the invention, each LED module includes an LED, a connector and a base plate, and the base plates are provided at the inside surfaces of the first base body, the second base body and the third base body, and the LED and the connector are provided on the base plate.

In one embodiment of the invention, the clip includes a first pressing part, a second pressing part formed by bending one side of the first pressing part, a third pressing part formed by bending the other side of the first pressing part, a first clip body connected with the second pressing part, and a second clip body connected with the third pressing part. The first pressing part, the second pressing part and the third pressing part press against the LED modules on the first base body, the second base body and the third base body, respectively. In addition, the first clip body fastens the second base body, and the second clip body fastens the third base body.

In one embodiment of the invention, each of the first pressing part, the second pressing part and the third pressing part has a holding structure to enable the LED modules to be fixed to the predetermined positions of the base.

In one embodiment of the invention, each of the first clip body and the second clip body includes a hook, each of the second base body and the third base body has a slot, and the hook fastens the slot to limit the displacement of the clip relative to the base along a first axis.

In one embodiment of the invention, each of the first clip body and the second clip body further includes at least a fastener, and the fasteners are fastened to the outside surface of the base to limit the displacement of the clip relative to the base along a second axis.

In one embodiment of the invention, the first axis and the second axis are perpendicular to each other.

In one embodiment of the invention, the clip is U-shaped.

In one embodiment of the invention, a surface of the clip faces the base and has a plurality of prominences, and the prominences press against the LED modules.

In one embodiment of the invention, the base is a heat dissipation base.

In one embodiment of the invention, a radiating fin assembly is provided at the outside surface of the heat dissipation base.

The invention utilizes a clip to fix a plurality of LED modules to the inside surface of the base. Compared with the conventional technology, the LED light source device of the invention is easy to be assembled.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is a schematic diagram showing a conventional LED light source device.

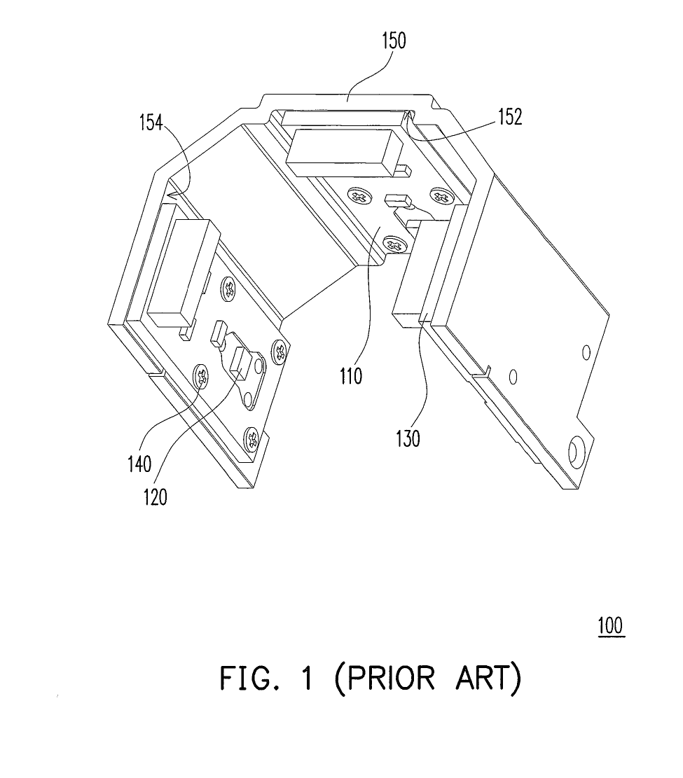

FIG. 2A is a combined diagram showing an LED light source device of one embodiment of the invention.

FIG. 2B is an exploded diagram showing the LED light source device in FIG. 2A.

### DETAILED DESCRIPTION OF THE EMBODIMENTS

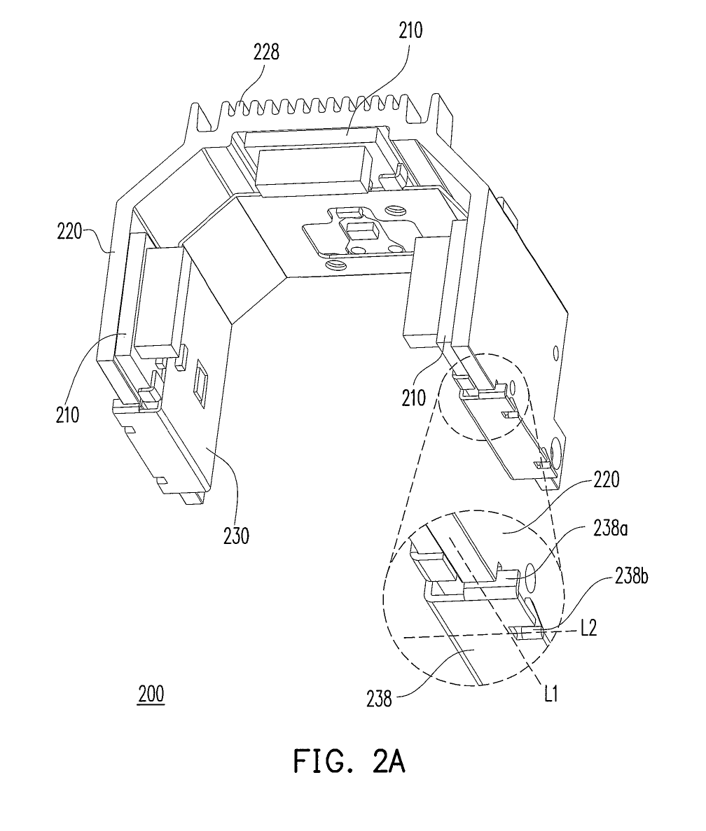

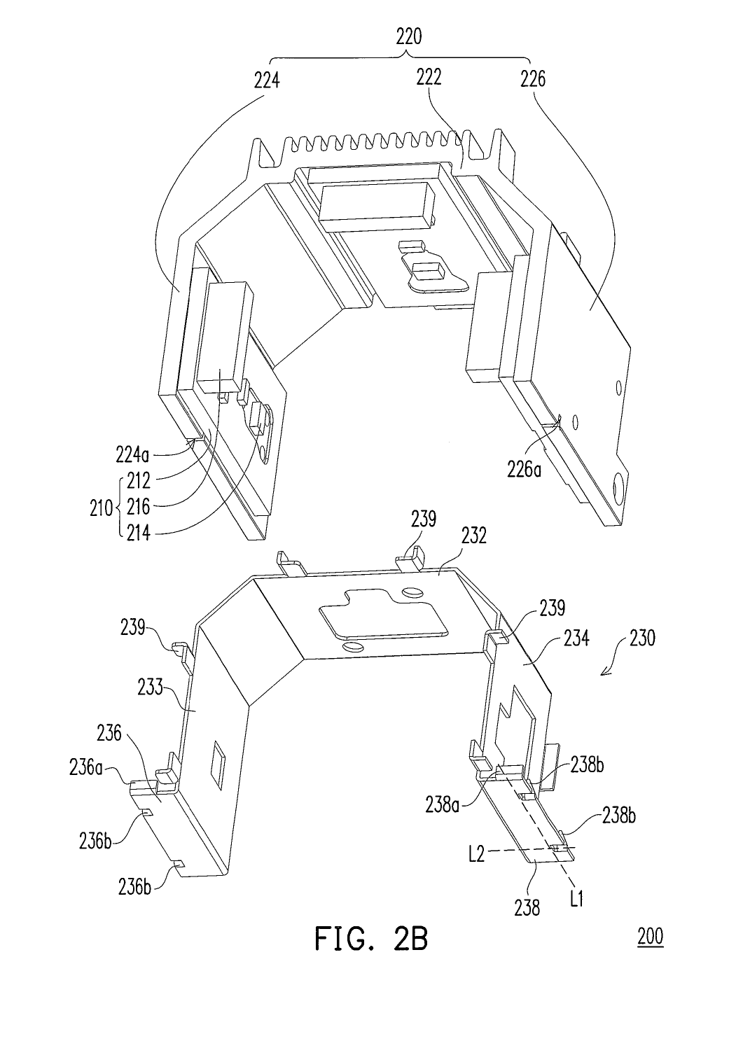

FIG. 2A is a combined diagram showing an LED light source device of one embodiment of the invention, and FIG. 2B is an exploded diagram showing the LED light source device in FIG. 2A. In the embodiment, as shown in FIG. 2A and FIG. 2B, an LED light source device 200 can be applied to a digital light processing projector (DLP projector), a liquid crystal display projector (LCD projector) or other light source device with high brightness. The LED light source device 200 includes a plurality of LED modules 210, a base 220 and a clip 230. In the embodiment, the base 220 is formed by a first base body 222, a second base body 224 and a third base body 226, and the second base body 224 and the third base body 226 extend from (in the embodiment, the second base body 224 and the third base body 226 are formed by bending two sides of the first base body) two sides of the first base body 222 and are corresponding to each other.

In the embodiment, the LED light source device 200 includes three LED modules 210. The three LED modules 210 include a red light LED module, a green light LED module and a blue light LED module. The three LED modules 210 are provided at inside surfaces of the first base body 222, the second base body 224 and the third base body 226, respectively. The clip 230 holds the LED modules 210. The clip 230 fastens the second base body 224 and the third base body 226 to enable the LED modules 210 to be tightly assembled at the base 220. Specifically, the LED module 210 of the embodiment includes a base plate 212 provided at the inside surface of the base body, an LED 214 provided on the base plate 212 and a connector 216. The clip 230 holds the base plate 212 to enable the base plate 212 to be tightly assembled at the base 220.

For understanding the connection relationship between the clip 230, and the LED module 210 and the base 220, the embodiment is illustrated hereinbelow in detail.

In FIG. 2A and FIG. 2B, the clip 230 of the embodiment is U-shaped, and the shape of the clip 230 corresponds to the shape of the base. The clip 230 includes a first pressing part 232, a second pressing part 233 which extends from (in the embodiment, the second pressing part 233 is formed by bending one side of the first pressing part 232) one side of the first pressing part 232, a third pressing part 234 which is formed by bending the other side of the first pressing part 232. The third pressing part 234 and the second pressing part 233 are corresponding to each other. The first pressing part 232, the second pressing part 233 and the third pressing part 234 press against the LED modules 210 on the first base body 222, the second base body 224 and the third base body 226.

The clip 230 of the embodiment further includes a first clip body 236 and a second clip body 238 in addition to including the first pressing part 232, the second pressing part 233 and the third pressing part 234. The first clip body 236 and the second clip body 238 are connected with the second pressing part 233 and the third pressing part 234, respectively. The first clip body 236 and the second clip body 238 are bent sheets which are formed by bending the second pressing part 233 and the third pressing part 234. When the first pressing part 232, the second pressing part 233 and the third pressing part 234 press against the LED modules 210 on the first base body 222, the second base body 224 and the third base body 226, the first clip body 236 can fastens the second base body 224 of the base 220, and the second clip body 238 can fastens the third base body 226 of the base 220 to enable the LED modules 210 to be firmly disposed on the base 220.

In further details, in the embodiment, the first clip body 236 and the second clip body 238 have a hook 236a and a hook 238a, respectively, and the second base body 224 and the third base body 226 have a slot 224a and a slot 226a, respectively. The hook 236a fastens the slot 224a, and the hook 238a fastens the slot 226a to limit the displacement of the clip 230 relative to the base 220 along a first axis L1. In addition, in the embodiment, the first clip body 236 and the second clip body 238 at least have fasteners 236b and 238b which fastens the outside surface of the base 220 to limit the displacement of the clip 230 relative to the base 220 along a second axis L2 (the second axis L2 is, for example, perpendicular to the first axis L1).

From the above, since when the clip 230 fastens the base 220, the displacements of the clip 230 along the first axis L1 and the second axis L2 are limited, the clip 230 is difficult to be removed from the base 220 by inappropriate external force. That is, the clip 230 of the embodiment can be effectively fastened on the base 220 further to enable the LED modules 210 firmly disposed at the inside surface of the base 220.

In addition, to enable the LED modules 210 firmly disposed at the first base body 222, the second base body 224 and the third base body 226, in the embodiment, a holding structure 239 whose shape is corresponding to the shape of the base plate 212 is disposed at each of the first pressing part 232, the second pressing part 233 and the third pressing part 234 of the clip 230 to limit the LED modules 210 to a predetermined position on the base 220. In this way, the LED modules 210 disposed on the first base body 222, the second base body 224 and the third base body 226 are difficult to be removed by the collision of external force.

In addition, the base 220 may also be a heat dissipation base, and a radiating fin assembly 228 is disposed at the outside surface of the base 220, and the base plate 212 is an aluminum base plate. Therefore, the heat energy generated by the LED 214 can be effectively conducted to the base 220 with the radiating fin assembly 228 via the aluminum base plate 212 and be dissipated to the ambient environment via the heat convection effect.

In the embodiment, the surface of the clip 230 faces the base 220 and can also has a plurality of prominences (not shown), and when the clip 230 fastens the base 220, the force that the clip 230 applies to the LED modules 210 can be concentrated at the base plate 212 via the prominences to enable the LED modules 210 further firmly disposed at the predetermined position on the base 220. When the prominences are provided on the surface of the clip 230, which faces the base 220, the LED modules 210 and the base 220 can also have preferred joining relationship.

To sum up, in the LED module of the embodiment of the present invention, a clip can be effectively fastened to a base to enable a plurality of LED modules disposed at the inside surface of the base to be tightly assembled at the base. Compared with the conventional technology which utilizes fasteners such as screws to fix a plurality of LED modules on the base, the clip of the invention can fix a plurality of LED modules on the base. In addition, the mode of utilizing the clip to fix a plurality of LED modules on the base can effectively avoid the condition that an assembly tool may interfere with the base during a locking process. In other words, the LED modules of the invention are easy to be assembled.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A light emitting diode (LED) light source device comprising:
a plurality of LED modules;
a base having a first base body, a second base body, and a third base body, wherein the second base body and the third base body extend from two sides of the first base body, and the LED modules are disposed at inside surfaces of the first base body, the second base body and the third base body, respectively; and
a clip holding the LED modules and fastening the second base body and the third base body to enable the LED modules to be tightly assembled between the base and the clip.

2. The device according to claim 1, wherein each of the LED modules comprises an LED, a connector and a base plate, and each of the base plates is disposed at the inside surfaces of the first base body, the second base body and the third base body, respectively, and the LED and the connector are provided on the base plate.

3. The device according to claim 1, wherein the clip comprises:
a first pressing part;
a second pressing part extending from one side of the first pressing part;
a third pressing part extending from the other side of the first pressing part, wherein the first pressing part, the second pressing part and the third pressing part press against the LED modules on the first base body, the second base body and the third base body, respectively;
a first clip body connected with the second pressing part and fastening the second base body; and
a second clip body connected with the third pressing part and fastening the third base body.

4. The device according to claim 3, wherein each of the first pressing part, the second pressing part and the third pressing part has a holding structure.

5. The device according to claim 3, wherein each of the first clip body and the second clip body comprises a hook, each of the second base body and the third base body has a slot, and the hook fastens the slot.

6. The device according to claim 5, wherein each of the first clip body and the second clip body further comprises a fastener fastening the outside surface of the base.

7. The device according to claim 1, wherein the base and the clip are U-shaped.

8. The device according to claim 1, wherein a surface of the clip faces the base and has a plurality of prominences.

9. The device according to claim 1, wherein the base is a heat dissipation base.

10. The device according to claim 9, wherein a radiating fin assembly is disposed at the outside surface of the heat dissipation base.
